(19) United States
(12) Patent Application Publication
(10) Pub. No.: US 2025/0363918 A1
(43) Pub. Date: Nov. 27, 2025

(54) DISPLAY DEVICE AND METHOD FOR OPTICALLY COMPENSATING THE SAME

(71) Applicant: SAMSUNG DISPLAY CO., LTD., YONGIN-SI (KR)

(72) Inventor: Si Beak PYO, Yongin-si (KR)

(21) Appl. No.: 19/013,378

(22) Filed: Jan. 8, 2025

(30) Foreign Application Priority Data
May 27, 2024 (KR) 10-2024-0068532

(51) Int. Cl. G09G 3/00; G09G 3/3225

(52) U.S. Cl. CPC G09G 3/006; G09G 3/3225; G09G 2320/0233; G09G 2320/0276; G09G 2320/0646; G09G 2360/147

(57) ABSTRACT

A method for optically compensating a display device including a plurality of pixels, a first pixel area including a plurality of first pixels of the pixels, and a second pixel area including a plurality of second pixels of the pixels, includes performing, sequentially, a first optical compensation for each of a plurality of first test voltages for gradations of a first range applied to each of the pixels, and performing, sequentially, a second optical compensation for each of a plurality of second test voltages for gradations of a second range applied to a first pixel of the first pixel area.

### CROSS-REFERENCE TO RELATED APPLICATION

This application claims priority under 35 U.S.C. § 119(a) to, and the benefit of Korean Patent Application No. 10-2024-0068532, filed on May 27, 2024, which is hereby incorporated by reference for all purposes as if fully set forth herein.

### BACKGROUND

### Field

The present invention relates to a display device and a method for optical compensation of a display device.

### Discussion

A display device may display an image using pixels (or pixel circuits). The display device may include a sensor or a camera in a bezel (or border portion) on a front of the display device (for example, a surface where an image may be displayed). For example, the display device may recognize an object using an optical sensor and acquire a photo or video using a camera.

In support of an industry trend toward relatively small bezels and large pixels areas, the cameras may be disposed to overlap the pixel area. With a camera disposed in a pixel area, a transmittance of an aera where the camera is disposed may affect image quality. In order to improve the transmittance of the area where the camera is disposed, a resolution of the overlapping area may be designed to be lower than that of other areas.

### SUMMARY

A display device and a method for optical compensation of a display device according to embodiments of the present invention may optically compensate for an area that emits light with higher luminance than other areas.

In accordance with an aspect of the present disclosure and given a display device including pixels, each of the pixels being included in one of a first pixel area or a second pixel area, a method for optically compensating the display device may include performing, sequentially, a first optical compensation for each of a plurality of first test voltages for gradations of a first range applied to each of the pixels, and performing, sequentially, a second optical compensation for each of a plurality of second test voltages for gradations of a second range applied to a first pixel of the first pixel area.

The performing the first optical compensation for each of the plurality of first test voltages may include correcting a first test voltage of the plurality of first test voltages for a gradation of the gradations of the first range so that each of the pixels emits light of a target luminance for the gradation.

The performing the first optical compensation for each first test voltage of the plurality of first test voltages may include applying a first test voltage for a gradation of the gradations of the first range to each of the pixels; measuring a luminance of light emitted from the pixels; and comparing the luminance of light emitted from the pixels to a target luminance for the gradation of the gradations of the first range, and determining a corrected first test voltage for the gradation based on the comparison.

The performing the second optical compensation for each second test voltage of the plurality of second test voltages may include correcting a second test voltage of the plurality of first test voltages for a second gradation among the gradations of the second range so that a first pixel of the first pixel area emits light of a target luminance for the gradation.

The performing the second optical compensation for each second test voltage of the plurality of second test voltages may include applying a second test voltage for a second gradation among the gradations of the second range to the first pixel, and applying a corrected first test voltage for a first gradation among the gradations of the first range to a second pixel of the first pixel area; measuring a luminance of light emitted from the pixels of the first pixel area; and correcting the second test voltage for the second gradation so that the luminance of light emitted from the pixels of the first pixel area becomes a reference luminance, wherein the second test voltage associated with the reference luminance is a corrected second test voltage.

The reference luminance may be less than or equal to a maximum measured luminance of a measuring device that measures the luminance.

In the first pixel area, the first pixel and the second pixel may be alternately arranged in a first direction and a second direction intersecting the first direction.

The first gradation may be determined according to the second gradation.

The first gradation may be lower than the second gradation.

The first gradation may decrease as the second gradation increases.

The gradations of the first range may be lower than the gradations of the second range. The second gradation may be 511, and the first gradation may be 0.

The second gradation may be 442, and the first gradation may be 283.

A number of pixels arranged per unit area in the second pixel area may be greater than a number of pixels arranged per unit area in the first pixel area.

The display device may further include a camera, and the camera may be disposed to overlap the first pixel area.

In accordance with an aspect of the present disclosure and given a display device including a first pixel area and a second pixel area in which a number of pixels arranged per unit area is greater than that of the first pixel area, a method for optically compensating the display device may include applying a first test voltage for a first gradation among a first range of a plurality of gradations to a first pixel of the first pixel area; applying a second test voltage for a second gradation among a second range of the plurality of gradations to a second pixel of the first pixel area; measuring a luminance of light emitted from the pixels of the first pixel area; and correcting the second test voltage for a second gradation so that a measured luminance of light emitted from the pixels of the first pixel area becomes a reference luminance.

Applying the first test voltage may include correcting the first test voltage so that the first pixel emits light of a target luminance for the first gradation.

Applying the second test voltage may include correcting the second test voltage for the second gradation so that a second pixel emits light of a target luminance for the second gradation

A display device according to embodiments of the present invention may include a pixel unit including a first pixel area and a second pixel area in which a number of pixels arranged per unit area is greater than that of the first pixel area; and a data driver supplying data voltages to the pixels through data lines connected to the pixels. The data driver may provide the data voltages for a gradation of a first range to the pixels of the first pixel area, and provide the data voltages for a gradation of a second range to the pixels of the first pixel area.

The display device may further include a camera, and the camera may be disposed to overlap the first pixel area.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and together with the description, serve to explain principles of the inventive concepts.

FIG. 1 is a diagram illustrating a display device according to embodiments of the present invention.

FIG. 2 is a diagram illustrating a portion of a pixel unit in the display device of FIG. 1 according to an embodiment.

FIG. 3 is a diagram schematically illustrating a configuration of the display device according to embodiments of the present invention.

FIG. 4 is a diagram schematically illustrating a configuration of a system for first optical compensation and second optical compensation in the display device of FIG. 1.

FIG. 5 is a flowchart illustrating a method for optically compensating the pixel unit in the display device of FIG. 1.

FIG. 6 is a flowchart illustrating step S200 of FIG. 5.

FIG. 7 is a diagram illustrating step S210 of FIG. 6.

FIG. 8 is a diagram illustrating steps S220 and S230 of FIG. 6.

FIG. 9 is a flowchart illustrating step S300 of FIG. 5.

FIGS. 10 to 12 are diagrams illustrating steps S310 and S320 of FIG. 9.

FIG. 13 is a diagram illustrating steps S330 and S340 of FIG. 9.

### DETAILED DESCRIPTION

Hereinafter, preferred embodiments according to the disclosure are described in detail with reference to the accompanying drawings. It should be noted that in the following description, only portions necessary for understanding an operation according to the disclosure may be described, and descriptions of other portions may be omitted in order not to obscure the subject matter of the disclosure. In addition, the disclosure may be embodied in other forms without being limited to embodiments described herein. However, exemplary embodiments described herein are provided to thoroughly and completely describe the disclosed contents and to sufficiently convey the scope of the present description to a person of ordinary skill in the art.

Throughout the specification, in a case where a component is “connected” to another component, the components may be “directly connected” or the components may be “indirectly connected” with another element interposed therebetween. Terms used herein are for describing specific embodiments and are not intended to limit the disclosure. Throughout the specification, in a case where a certain portion “includes” a certain component, the portion may further include another component without excluding another component unless otherwise stated. “At least any one of X, Y, and Z” and “at least any one selected from a group consisting of X, Y, and Z” may be interpreted as X only, Y only, Z only, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features may be positioned in a direction “on” the other elements or features. Therefore, in an embodiment, the term “under” may include both directions of on and under. In addition, the device may face in other directions (for example, rotated 90 degrees or in other directions) and thus the spatially relative terms used herein may be interpreted according thereto.

In addition, embodiments of the disclosure may be described here with reference to schematic diagrams (and intermediate structures) of the present disclosure, so that changes in a shape as shown due to, for example, manufacturing technology and/or a tolerance may be expected. Therefore, embodiments disclosed herein may not be construed as being limited to shown specific shapes, and should be interpreted as including, for example, changes in shapes that occur as a result of manufacturing. As described herein, the shapes shown in the drawings may not show actual shapes of areas of a device, and embodiments are not limited thereto.

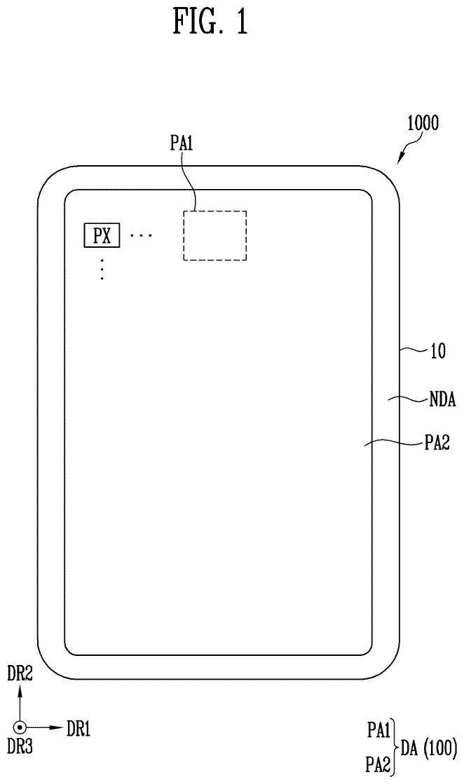

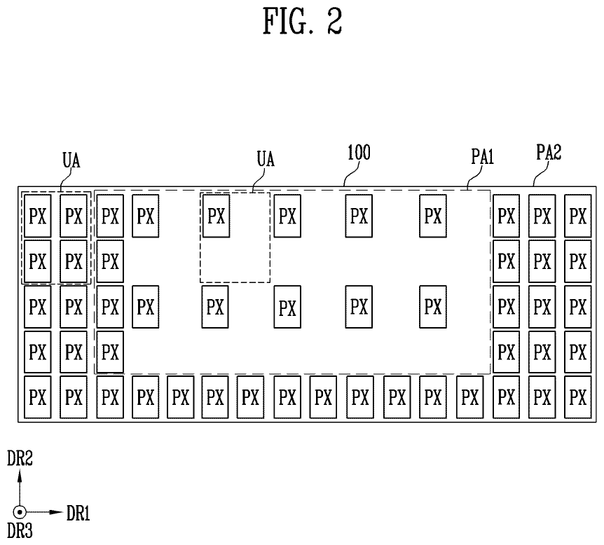

FIG. 1 is a diagram illustrating a display device according to embodiments of the present invention. FIG. 2 is a diagram illustrating a portion of a pixel unit in the display device of FIG. 1 according to an embodiment.

Referring to FIG. 1 and FIG. 2, a display device 1000 may include a display panel 10 having a pixel unit 100.

The display panel 10 may include a display area DA and a non-display area NDA. The non-display area NDA may be disposed at an edge of the display area DA. The non-display area NDA may surround the display area DA. Pixels PX may be disposed in the display area DA. Driving units for driving the pixels PX may be disposed in the non-display area NDA. The pixels PX may be arranged spaced apart from each other in a first direction DR1 and a second direction DR2 intersecting the first direction DR1.

The display area DA may correspond to the pixel unit 100 including a plurality of pixels PX. The pixel unit 100 may include a first pixel area PA1 and a second pixel area PA2. For example, the first pixel area PA1 may be disposed in the second pixel area PA2.

In an embodiment, as shown in FIG. 2, the number (or density) of pixels PX arranged per unit area UA may be different in the first pixel area PA1 and the second pixel area PA2. The number (or density) of pixels PX arranged per unit area UA may be greater in the second pixel area PA2 than in the first pixel area PA1. For example, in the first pixel area PA1, one pixel PX may be disposed per unit area UA, and in the second pixel area PA2, four pixels PX may be arranged per unit area UA. Accordingly, the resolution of the first pixel area PA1 may be lower than the resolution of the second pixel area PA2.

An aperture ratio of the first pixel area PA1 is higher than that of the second pixel area PA2. A device that senses or transmits light may be disposed to overlap the first pixel area PA1. For example, a camera or an optical sensor may be disposed to overlap the first pixel area PA1. The optical sensor may include a biometric sensor such as a fingerprint sensor, an iris recognition sensor, or an arterial sensor. However, this is an example, and the light-sensing type optical sensor may include a gesture sensor, a motion sensor, a proximity sensor, an illumination sensor, or an image sensor.

The number (or density) of pixels PX arranged per unit area UA may be different in the first pixel area PA1 and the second pixel area PA2. For example, the number (or density) of pixels PX in the second pixel area PA2 may be greater than the number (or density) of pixels PX in the first pixel area PA1. Accordingly, when the same (or substantially the same) data signal is supplied to the pixels PX of the first pixel area PA1 and the second pixel area PA2, the luminance in the second pixel area PA2 may be greater than in the first pixel area PA1. Also, the boundary between the first pixel area PA1 and the second pixel area PA2 may be visually recognized by a viewer.

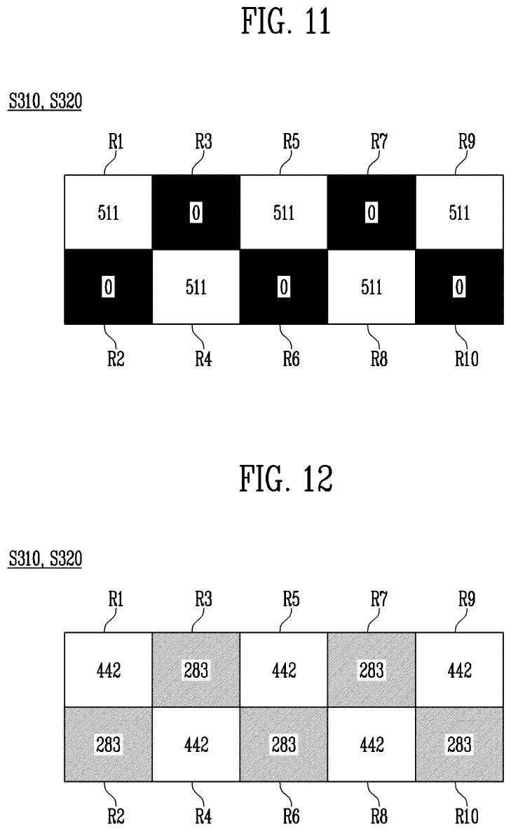

In the display device 1000 according to embodiments of the present invention, each of the pixels PX may emit light of 0 to 511 gradations. In the present description, light emitted by a pixel may be described in terms of gradations ranging from 0 to 511. That is, 512 different gradations may be displayed, where a gradation of 0 may correspond to a darkest luminance and a gradation of 511 may correspond to a lightest value (see for example, FIG. 11). Each gradation may represent a distinct gradation that a pixel may display. However, the 512 gradations may not be limiting. For example, luminance may be understood in other terms, such as candelas per square meter (e.g., cd/m²) or in terms of 256 gradations (e.g., gradations ranging from 0 to 255).

While the display device 1000 is driven, gradation ranges of light emitted by the pixels PX of the first pixel area PA1 and the pixels PX of the second pixel area PA2 may be different from each other. For example, while the display device 1000 is driven, the pixels PX of the first pixel area PA1 may emit light in a second range of gradations (for example, 374 to 511 gradations). On the other hand, while the display device 1000 is driven, the pixels PX of the second pixel area PA2 may emit light of in a first range of gradations (for example, 0 to 373 gradations). Through this, while the display device 1000 is driven, each of the pixels PX of the first pixel area PA1 may emit light with higher luminance than each of the pixels PX of the second pixel area PA2.

In an embodiment, a case where the first range is 0 to 373 and the second range is 374 to 511 has been described as an example, but the present invention is not limited thereto.

The number of pixels PX in the first pixel area PA1 and the second pixel area PA2 may be different. However, while the display device 1000 is driven, each of the pixels PX of the first pixel area PA1 may emit light with higher luminance. Through this, the first pixel area PA1 and the second pixel area PA2 may output the same (or substantially the same) luminance. In addition, a visibility of the boundary between the first pixel area PA1 and the second pixel area PA2 may be reduced or eliminated.

Hereinafter, a method for optically compensating for a difference between a luminance of the pixels PX of the first pixel area PA1 and a luminance of the second pixel area PA2 during a manufacturing process of the display device 1000 will be described in detail.

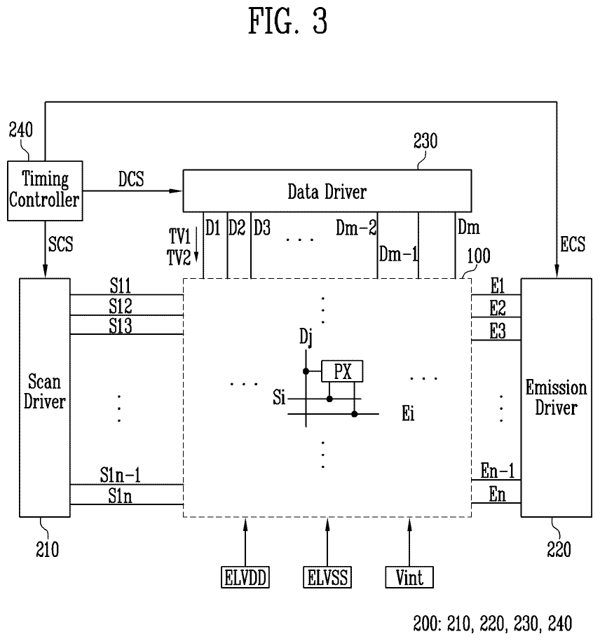

FIG. 3 is a diagram schematically illustrating a configuration of the display device according to embodiments of the present invention.

Referring to FIG. 3, a display device according to embodiments of the present invention may include a pixel unit 100 and a display driver 200. The display driver 200 may include a scan driver 210, an emission driver 220, a data driver 230, and a timing controller 240.

The timing controller 240 may generate a scan drive control signal SCS, a data drive control signal DCS, and an emission drive control signal ECS based on signals input from a processor (for example, a graphics processing unit (GPU)). The scan drive control signal SCS generated by the timing controller 240 may be supplied to the scan driver 210. The data drive control signal DCS generated by the timing controller 240 may be supplied to the data driver 230. The emission drive control signal ECS generated by the timing controller 240 may be supplied to the emission driver 220.

The scan driver 210 may generate a scan signal in response to the scan drive control signal SCS. The scan driver 210 may supply the scan signal to scan lines S11 to S1n. For example, the scan driver 210 may sequentially supply the scan signal to the scan lines S11 to S1n.

When the scan signal is sequentially supplied to the scan lines S11 to S1n, pixels PX may be selected in units of horizontal lines. To this end, the scan signal may be set to a gate-on voltage (for example, a low-level voltage) so that transistors included in the pixels PX can be turned on. The data driver 230 may generate data voltages in response to the data drive control signal DCS. The data voltages may include first test voltages TV1 and second test voltages TV2 described herein. The data driver 230 may supply the data voltages to data lines D1 to Dm. The data voltages supplied to the data lines D1 to Dm may be supplied to the pixels PX selected by the scan signal. In the display device according to embodiments of the present invention, the pixels PX may emit light of 0 to 511 gradations depending on the data voltages supplied from the data driver 230.

According to an aspect of the present disclosure, an optical compensation may be performed on the display device 1000. For example, the optical compensation may be performed during a manufacturing process of the display device 1000. The optical compensation may include first optical compensation and second optical compensation.

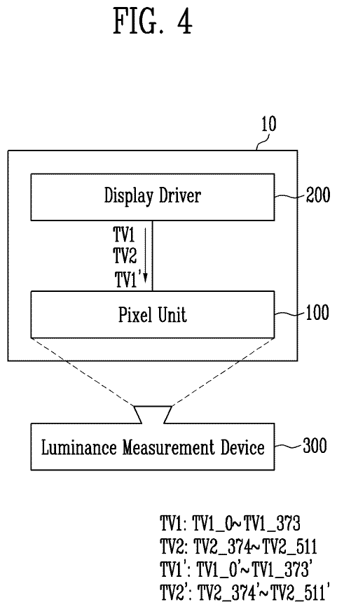

For example, at a first time, the data driver 230 may supply the first test voltages TV1 to the pixel unit 100 in response to the data drive control signal DCS. Here, the first time may refer to a period in which the first optical compensation is performed. In addition, the first test voltages TV1 may be optically compensated for based on a luminance measured by a luminance measurement device 300 (see FIG. 4). Optically compensated first test voltages TV1 may be corrected first test voltages TV1′. In addition, corrected first test voltages TV1′ may be stored. For example, the corrected first test voltages TV1′ for each gradation may be stored in the form of a data voltage for each gradation. For example, the corrected first test voltages TV1′ for each gradation may be stored in the form of a correction value for each gradation. The corrected first test voltages TV1′ may be voltages determined to achieve an expected luminance.

The corrected first test voltages TV1′ may be stored in a memory device. The memory device may be included in any one of the data driver 230 or the timing controller 240, or may be included in the display device as a component different from the data driver 230 and the timing controller 240.

At a second time different from the first time, the data driver 230 may supply the second test voltages TV2 to the first pixel area PA1 in response to the data drive control signal DCS. Here, the second time may refer to a period in which the second optical compensation is performed. In addition, the second test voltages TV2 may be optically compensated based on a luminance measured by the luminance measurement device 300. Optically compensated second test voltages TV2 may be corrected second test voltages TV2′. In addition, corrected second test voltages TV2′ may be stored in the data driver 230. For example, the corrected second test voltages TV2′ for each gradation may be stored in the form of a data voltage for each gradation. For example, the corrected second test voltages TV2′ for each gradation may be stored in the form of a correction value for each gradation.

The corrected second test voltages TV2′ may be stored in a memory device. The memory device may be included in any one of the data driver 230 or the timing controller 240, or may be included in the display device as a component different from the data driver 230 and the timing controller 240.

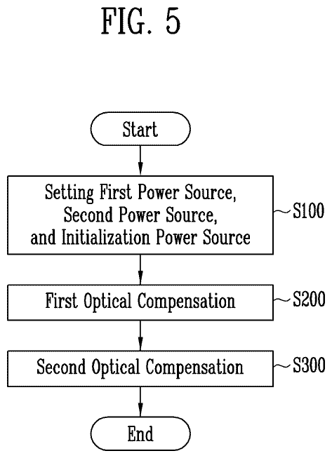

An example optical compensation is be described in detail below with reference to FIGS. 5 to 13.

The emission driver 220 may generate an emission control signal in response to the emission drive control signal ECS. The emission driver 220 may supply the emission control signal to emission control lines E1 to En. As an example, the emission driver 220 may sequentially supply the emission control signal to the emission control lines E1 to En.

When the emission control signal is sequentially supplied to the emission control lines E1 to En, the pixels PX may not emit light in units of horizontal lines. To this end, the emission control signal may be set to a gate-off voltage (for example, a high-level voltage) so that transistors included in the pixels PX can be turned off.

Referring to FIG. 3, the scan driver 210 and the emission driver 220 are shown as separate components, but embodiments of the present invention are not limited thereto. For example, the scan driver 210 and the emission driver 220 may be implemented in a same driver.

In addition, the scan driver 210 and/or the emission driver 220 may be mounted on a substrate through a thin film manufacturing process.

In addition, the scan driver 210 and/or the emission driver 220 may be located on a same side or on different sides of the pixel unit 100.

The pixel unit 100 may include a plurality of pixels PX connected to the data lines D1 to Dm, the scan lines S11 to S1n, and the emission control lines E1 to En.

The pixels PX may receive an initialization power source Vint, a first power source ELVDD, and a second power source ELVSS from an external source (or a power supply unit (not shown)).

Each of the pixels PX may be selected when a scan signal is supplied to the connected scan lines S11 to S1n. Each of the pixels PX may receive a data voltage from the connected data lines D1 to Dm. The pixel PX receiving the data voltage may control the amount of current flowing from the first power source ELVDD to the second power source ELVSS via an organic light emitting diode (not shown) in response to the data voltage.

In this case, the organic light emitting diode may generate light with a predetermined luminance in response to an amount of current applied to the organic light emitting diode. Additionally, the first power source ELVDD may be set to a higher voltage than the second power source ELVSS.

FIG. 3 shows a case where the pixel PX is connected to a scan line S1i, a data line D1j, and an emission control line Ei as an example, but embodiments of the present invention are not limited thereto. In other words, depending on a circuit structure of the pixel PX, the number of scan lines S11 to S1n connected to the pixel PX may be plural, and the number of emission control lines E1 to En connected to the pixel PX may be plural.

In addition, in some cases, the pixel PX may be connected to the scan lines S11 to S1n and the data lines D1 to Dm. For example, the emission control lines E1 to En and the emission driver 220 for driving the emission control lines E1 to En may be omitted.

FIG. 4 is a diagram schematically illustrating a configuration of a system for first optical compensation and second optical compensation in the display device of FIG. 1.

Referring to FIG. 1 and FIG. 4, a system for first optical compensation and second optical compensation of a display device may include a display panel 10 and a luminance measurement device 300. The display panel 10 may include the pixel unit 100 and the display driver 200.

In addition, the display driver 200 may include the scan driver 210, the emission driver 220, the data driver 230, and the timing controller 240 shown in FIG. 3.

The first test voltages TV1 may include first test voltages TV1_0 to TV1_373 for gradations of the first range. The second test voltages TV2 may include second test voltages TV2_374 to TV2_511 for gradations of the second range. For convenience of description, in the following description, it is assumed that the gradations of the first range may include 0 to 373 gradations and the gradations of the second range may include 374 to 511 gradations.

Referring to the first optical compensation of the display device 1000, in response to the data drive control signal DCS, the data driver 230 may sequentially supply the first test voltages TV1_0 to TV1_373 for 0 to 373 gradations to each of the pixels PX of the pixel unit 100. For example, the data driver 230 may supply a first test voltage TV1_0 for a 0 gradation to each of the pixels PX. Subsequently, the data driver 230 may supply a first test voltage TV1_1 for a 1 gradation to each of the pixels PX. Subsequently, the data driver 230 may supply a first test voltage TV1_2 for a 2 gradation to each of the pixels PX. In this way, the data driver 230 may sequentially supply first test voltages TV1_3 to TV1_373 for gradations 3 to 373 to each of the pixels PX.

When the first test voltages TV1 are supplied to the pixel unit 100, light may be emitted from the pixels PX. The luminance measurement device 300 may measure the luminance of the light emitted from the pixels PX.

The first test voltages TV1 may be corrected by comparing the measured luminance to a target luminance. For example, a first test voltage TV1_373 for a 373 gradation may be supplied to the pixels PX, and the luminance of the pixels PX may be measured by the luminance measurement device 300. In addition, the first test voltage TV1_373 for a 373 gradation may be corrected so that the measured luminance is 2175 Nits, which may be the target luminance. The same procedure may be performed for the remaining first test voltages TV1. The corrected first test voltages TV1′ may be stored in various forms. The corrected first test voltages TV1′ may include voltages for the 0 to 373 gradations.

Referring to the second optical compensation of the display device 1000, in the pixel unit 100, the pixels PX of the first pixel area PA1 may be divided into first pixels and second pixels.

The data driver 230 of the display driver 200 may simultaneously supply different voltages to different pixels of the first pixel area PA1. For example, the data driver 230 of the display driver 200 may simultaneously supply a first voltage to some pixels (hereinafter referred to as first pixels) of the first pixel area PA1 and a second voltage to the remaining pixels (hereinafter referred to as second pixels) of the first pixel area PA1.

In response to the data drive control signal DCS, the data driver 230 may sequentially supply the second test voltages TV2_374 to TV2_511 for the 374 to 511 gradations to each of the first pixels. Further, in response to the data drive control signal DCS, the data driver 230 may supply corrected first test voltages TV1_0′ to TV1_373′ for the 0 to 373 gradations to each of the second pixels.

For example, the data driver 230 may supply a second test voltage TV2_511 for the 511 gradation to each of the first pixels. At the same time, the data driver 230 may supply a corrected first data voltage TV1_0′ for the 0 gradation to each of the second pixels.

For example, the data driver 230 may supply a second test voltage TV2_442 for a 442 gradation to each of the first pixels. At the same time, the data driver 230 may supply a corrected first data voltage TV1_282′ for a 282 gradation to each of the second pixels.

In this way, the data driver 230 may supply a second test voltage TV2_M for an M gradation to each of the first pixels. At the same time, the data driver 230 may supply a corrected first data voltage TV1_L′ for an L gradation to each of the second pixels. Here, M may be an integer greater than or equal to 374 and less than or equal to 511, and L may be an integer greater than or equal to 0 and less than or equal to 373.

A value of L may be determined depending on a value of M, and the value of L may decrease as the value of M increases.

The pixels PX of the first pixel area PA1 may emit light according to the supply of the second test voltages TV2 and the corrected first test voltages TV1′. The luminance measurement device 300 may measure the luminance of the light emitted from the pixels PX of the first pixel area PA1. For example, the luminance measurement device 300 may measure the luminance of light emitted by the first pixels and the second pixels. The luminance measured by the luminance measurement device 300 may be an average luminance of the light emitted from the first pixels or the second pixels.

The second test voltages TV2 may be corrected so that the measured luminance becomes a reference luminance. Here, the reference luminance may be less than or equal to a high luminance measured by the luminance measurement device 300. For example, the high luminance measured by the luminance measurement device 300 may be a maximum luminance measured by the luminance measurement device 300. For example, the reference luminance may be 2175 Nits. The corrected second test voltages TV2′ may include corrected voltages for the 374 to 511 gradations.

To achieve a substantially uniform luminance across the pixel unit 100, the pixels PX of the first pixel area PA1 may display a higher gradation than the pixels PX of the second pixel area PA2. In the step of performing the second optical compensation, if all the pixels PX of the first pixel area PA1 display a gradation of the second range, the luminance of the emitted light may exceed the high luminance measured by the luminance measurement device 300. Accordingly, an optical compensation method according to embodiments of the present invention may cause the pixels PX of the first pixel area PA1 to display gradations in the form of a pattern in the step of performing the second optical compensation. In addition, the second optical compensation may be performed by comparing the luminance of light measured by the luminance measurement device 300 and the reference luminance. Here, the reference luminance may be less than or equal to the high luminance measured by the luminance measurement device 300.

FIG. 5 is a flowchart illustrating a method for optically compensating the pixel unit in the display device of FIG. 1.

Referring to FIGS. 1 to 5, in step S100, the first power source ELVDD, the second power source ELVSS, and the initialization power source Vint supplied to the pixel unit 100 may be set.

In step S200, the display device 1000 may perform a first optical compensation.

In step S300, the display device 1000 may perform a second optical compensation.

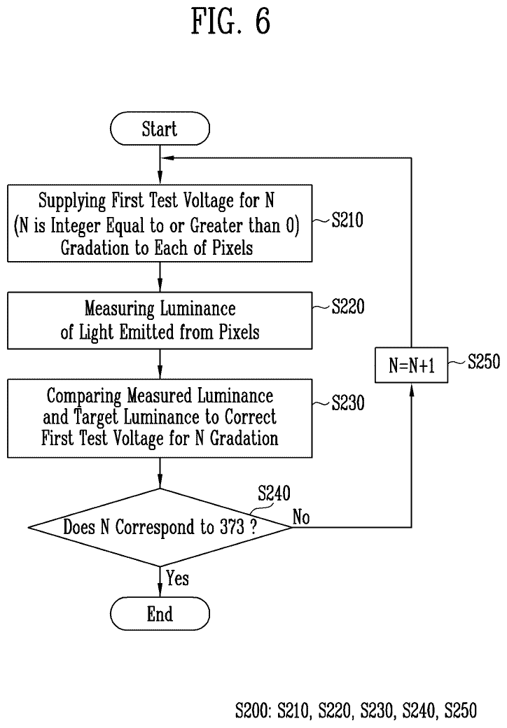

FIG. 6 is a flowchart illustrating step S200 of FIG. 5 in detail.

Referring to FIG. 5 and FIG. 6, in step S210, the data driver 230 may supply a first test voltage TV1_N for an N gradation to each of the pixels PX of the pixel unit 100, where N may be an integer equal to or greater than 0.

In step S220, the luminance of light emitted from the pixels PX may be measured using the luminance measurement device 300.

In step S230, the first test voltage TV1_N for the N gradation may be corrected so that the pixels PX supplied with the first test voltage TV1_N for the N gradation emit light of a target luminance. A corrected first test voltage TV1_N′ for the N gradation may be stored in the data driver 230. That is, step S230 may include determining a corrected first test voltage TV1_N′ for the N gradation based on a comparison of the measured luminance to the target luminance.

In step S240, it may be determined whether N corresponds to 373. It can be terminated when N is 373. If N is not 373, in step S250, the next grayscale, (N+1) grayscale, may be selected as the N gradation. Subsequently, the steps S210 to S240 may be performed again.

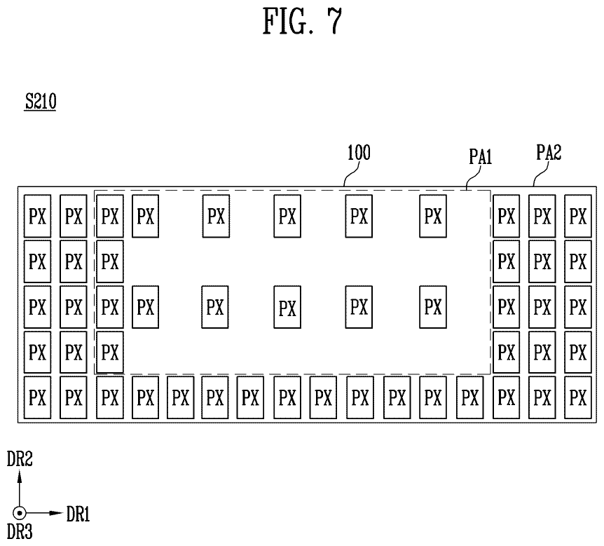

FIG. 7 is a diagram illustrating step S210 of FIG. 6.

Referring to FIG. 6 and FIG. 7, the pixel unit 100 may include pixels PX. Each of the pixels PX may be included in one of the first pixel area PA1 or the second pixel area PA2.

The data driver 230 may supply the first test voltage TV1_N for N gradation to each of the pixels PX through the data lines D1 to Dm in response to the data drive control signal DCS, where N may be an integer greater than 0.

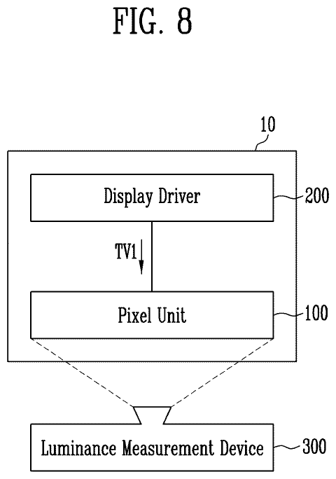

FIG. 8 is a diagram illustrating steps S220 and S230 of FIG. 6.

Referring to FIG. 6 and FIG. 8, when the first test voltage TV1_N for the N gradation is supplied to the pixel unit 100, light may be emitted from the pixels PX. The luminance measurement device 300 may measure the luminance of the light emitted from the pixels PX.

The first test voltage TV1_N for the N gradation may be corrected by comparing the measured luminance to the target luminance. The first test voltage TV1_N for the N gradation may be corrected so that the pixels PX supplied with the first test voltage TV1_N for the N gradation emit light of the target luminance. For example, the data driver 230 may correct a first test voltage TV1_373 for the 373 gradation so that the pixels PX supplied with the first test voltage TV1_373 for the 373 gradation emits light of 2175 Nits.

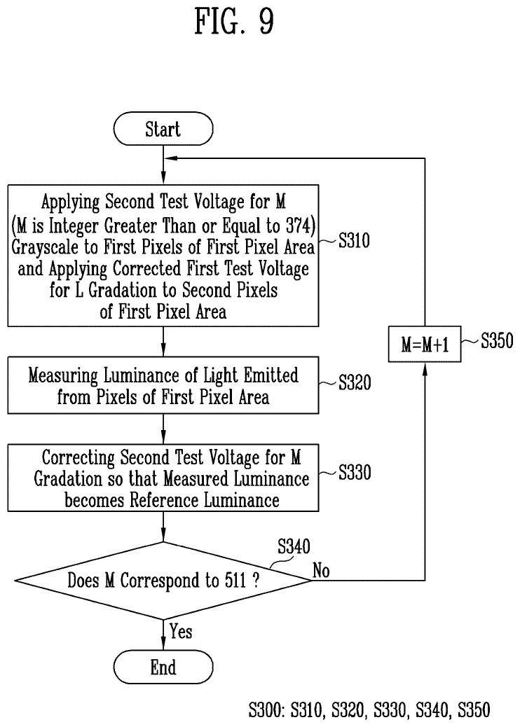

A corrected first test voltage TV1_N′ for the N gradation may be stored in the data driver 230. The corrected first test voltage TV1_N′ for the N gradation may be stored in various forms. FIG. 9 is a flowchart illustrating step S300 of FIG. 5 in detail.

Referring to FIG. 5 and FIG. 9, in step S310, the data driver 230 may supply a second test voltage TV2_M for the M gradation to the first pixels of the first pixel area PA1, where M may be an integer greater than or equal to 374. At the same time, the data driver 230 may supply a corrected first test voltage TV1_L′ for the L gradation to the second pixels of the first pixel area PA1. A value of L may be determined according to a value of M.

In step S320, the luminance of light emitted from the pixels PX of the first pixel area PA1 may be measured using the luminance measurement device 300.

In step S330, the second test voltage TV2_M for the M gradation may be corrected so that the measured luminance becomes the reference luminance. Here, the reference luminance may be less than or equal to the high luminance measured by the luminance measurement device 300. For example, the reference luminance may be 2175 Nits. A corrected second test voltage TV2_M′ for the M gradation may be stored in the data driver 230.

In step S340, it may be determined whether M corresponds to 511. A loop including steps S310, S320, and S330 can be terminated when M is 511. If M is not 511, in step S350, the next grayscale, (M+1) grayscale, may be selected as the M gradation. Subsequently, the steps S310 to S340 may be performed again.

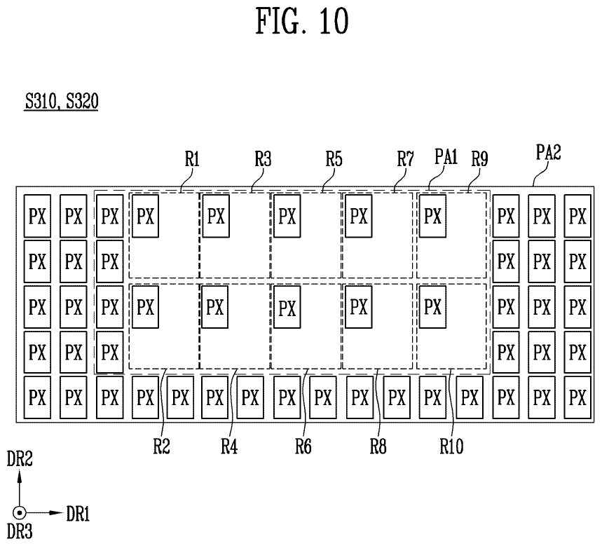

FIG. 10, FIG. 11, and FIG. 12 are diagrams illustrating steps S310 and S320 of FIG. 9.

Referring to FIG. 10, FIG. 11, and FIG. 12, the pixel unit 100 may include pixels PX. Each of the pixels PX may be included in one of the first pixel area PA1 or the second pixel area PA2.

The pixels PX of the first pixel area PA1 may correspond to one of a first pixel or a second pixel. Also, the first pixel and the second pixel may be alternately arranged in the first direction DR1 and the second direction DR2.

As shown in FIG. 10, the first pixel area PA1 may include first to tenth sub-areas R1 to R10. However, embodiments of the present invention may not be limited thereto, and the first pixel area PA1 may include more or less than 10 sub-areas. Hereinafter, the description will be made assuming that the first pixel area PA1 includes 10 sub-areas.

Pixels PX included in the first sub-area R1, the fourth sub-area R4, the fifth sub-area R5, the eighth sub-area R8, and the ninth sub-area R9 may correspond to the first pixel. Pixels PX included in other sub-areas may correspond to the second pixel.

However, embodiments of the present invention may not be limited thereto. For example, pixels PX included in the first sub-area R1, the fourth sub-area R4, the fifth sub-area R5, the eighth sub-area R8, and the ninth sub-area R9 may correspond to the second pixel, and pixels PX included in other sub-areas may correspond to the first pixel.

Hereinafter, a description will be made assuming that the pixels PX included in the first sub-area R1 correspond to the first pixel.

The data driver 230 of the display driver 200 may simultaneously apply different voltages to different pixels of the first pixel area PA1. For example, the data driver 230 of the display driver 200 may simultaneously supply a first voltage to some pixels (hereinafter referred to as first pixels) of the first pixel area PA1 and a second voltage to the remaining pixels (hereinafter referred to as second pixels) of the first pixel area PA1.

The data driver 230 may sequentially supply second test voltages TV2_374 to TV2_511 for 374 to 511 gradations to each of the first pixels. The data driver 230 may supply corrected first test voltages TV1_0′ to TV1_373′ for 0 to 373 gradations to each of the second pixels.

For example, as shown in FIG. 11, the data driver 230 may supply a second test voltage TV2_511 for the 511 gradation to each of the first pixels. At the same time, the data driver 230 may supply a corrected first data voltage TV1_0′ for the 0 gradation to each of the second pixels.

For example, as shown in FIG. 12, the data driver 230 may supply a second test voltage TV2_442 for the 442 gradation to each of the first pixels. At the same time, the data driver 230 may supply a corrected first data voltage TV1_282′ for the 282 gradation to each of the second pixels.

In this way, the data driver 230 may supply the second test voltage TV2_M for the M gradation to each of the first pixels. At the same time, the data driver 230 may supply the corrected first data voltage TV1_L′ for the L gradation to each of the second pixels. Here, M may be an integer greater than or equal to 374 and less than or equal to 511, and L may be an integer greater than or equal to 0 and less than or equal to 373.

The value of L may be determined depending on the value of M, and the value of L may decrease as the value of M increases.

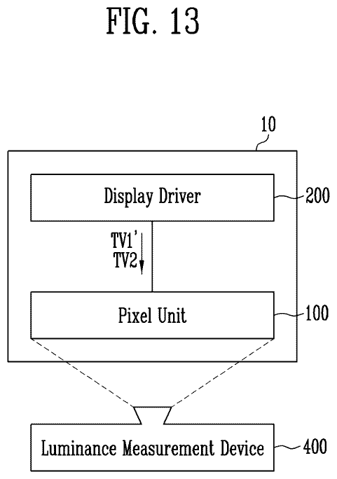

FIG. 13 is a diagram illustrating steps S330 and S340 of FIG. 9.

Referring to FIG. 9 and FIG. 13, the pixels PX of the first pixel area PA1 may emit light according to the supply of the second test voltages TV2 and the corrected first test voltages TV1′. The luminance measurement device 300 may measure the luminance of the light emitted from the pixels PX of the first pixel area PA1. For example, the luminance measurement device 300 may measure the luminance of light emitted by the first pixels and the second pixels. The luminance measured by the luminance measurement device 300 may be an average luminance of the light emitted from the first pixels or the second pixels.

The second test voltages TV2 may be corrected so that the measured luminance becomes the reference luminance. Here, the reference luminance may be less than or equal to the high luminance measured be the luminance measurement device 300. For example, the reference luminance may be 2175 Nits. The corrected second test voltages TV2′ may be stored in the data driver 230 in various forms. For example, the corrected second test voltages TV2′ for each gradation may be stored in the form of a data voltage for each gradation. For example, the corrected second test voltages TV2′ for each gradation may be stored in the form of a correction value for each gradation.

According to a display device and a method for optically compensating the same according to embodiments of the present invention, optical compensation can be performed in an area that emits light with a different luminance than another area.

Effects according to embodiments are not limited by the present specification, and more various other effects are included in the present specification.

Although specific embodiments and implementations have been described herein, other embodiments and modifications may be derived from the foregoing descriptions. Accordingly, the spirit of the present disclosure is not limited by the present specification, but may also be applied to the claims set forth below, various obvious modifications, and equivalents.

What is claimed is:

1. A method for optically compensating a display device including a plurality of pixels, a first pixel area including a plurality of first pixels of the pixels, and a second pixel area including a plurality of second pixels of the pixels, method comprising:
performing, sequentially, a first optical compensation for each of a plurality of first test voltages for gradations of a first range applied to each of the pixels; and
performing, sequentially, a second optical compensation for each of a plurality of second test voltages for gradations of a second range applied to a first pixel of the first pixel area.

2. The method of claim 1, wherein the performing the first optical compensation for each of the plurality of first test voltages includes correcting a first test voltage of the plurality of first test voltages for a gradation of the gradations of the first range so that each of the pixels emits light of a target luminance for the gradation.

3. The method of claim 1, wherein the performing the first optical compensation for each first test voltage of the plurality of first test voltages includes:
applying a first test voltage for a gradation of the gradations of the first range to each of the pixels;
measuring a luminance of light emitted from the pixels;
comparing the luminance of light emitted from the pixels to a target luminance for the gradation of the gradations of the first range; and
determining a corrected first test voltage for the gradation based on the comparison.

4. The method of claim 1, wherein the performing the second optical compensation for each second test voltage of the plurality of second test voltages includes correcting a second test voltage of the plurality of first test voltages for a second gradation among the gradations of the second range so that a first pixel of the first pixel area emits light of a target luminance for the gradation.

5. The method of claim 1, wherein the performing the second optical compensation for each second test voltage of the plurality of second test voltages includes:
applying a second test voltage for a second gradation among the gradations of the second range to the first pixel, and applying a corrected first test voltage for a first gradation among the gradations of the first range to a second pixel of the first pixel area;
measuring a luminance of light emitted from the pixels of the first pixel area; and
correcting the second test voltage for the second gradation so that the luminance of light emitted from the pixels of the first pixel area becomes a reference luminance, wherein the second test voltage associated with the reference luminance is a corrected second test voltage.

6. The method of claim 5, wherein the reference luminance is less than or equal to a maximum measured luminance of a measuring device that measures the luminance.

7. The method of claim 5, wherein in the first pixel area, the first pixel and the second pixel are alternately arranged in a first direction and a second direction intersecting the first direction.

8. The method of claim 5, wherein the first gradation is determined according to the second gradation.

9. The method of claim 8, wherein the first gradation is lower than the second gradation.

10. The method of claim 8, wherein the first gradation decreases as the second gradation increases.

11. The method of claim 1, wherein the gradations of the first range are lower than the gradations of the second range.

12. The method of claim 5, wherein the second gradation is 511, and the first gradation is 0.

13. The method of claim 5, wherein the second gradation is 442, and the first gradation is 283.

14. The method of claim 1, wherein a number of pixels arranged per unit area in the second pixel area is greater than a number of pixels arranged per unit area in the first pixel area.

15. The method of claim 1, wherein the display device further includes a camera, and
wherein the camera is disposed to overlap the first pixel area.

16. A method for optically compensating a display device including a first pixel area and a second pixel area in which a number of pixels arranged per unit area is greater than that of the first pixel area, the method comprising:
applying a first test voltage for a first gradation among a first range of a plurality of gradations to a first pixel of the first pixel area;
applying a second test voltage for a second gradation among of a second range of the plurality of gradations to a second pixel of the first pixel area;
measuring a luminance of light emitted from the pixels of the first pixel area; and
correcting the second test voltage for the second gradation so that a measured luminance of light emitted from the pixels of the first pixel area becomes a reference luminance.

17. The method of claim 16, wherein applying the first test voltage includes correcting the first test voltage so that the first pixel emits light of a target luminance for the first gradation.

18. The method of claim 17, wherein applying the second test voltage includes correcting the second test voltage for the second gradation so that a second pixel emits light of a target luminance for the second gradation.

19. A display device comprising:
a pixel unit including a first pixel area and a second pixel area in which a number of pixels arranged per unit area is greater than that of the first pixel area; and
a data driver supplying data voltages to the pixels through data lines connected to the pixels,
wherein the data driver provides the data voltages for a gradation of a first range to the pixels of the first pixel area, and provides the data voltages for a gradation of a second range to the pixels of the first pixel area.

20. The display device of claim 19, wherein the display device further includes a camera, and
wherein the camera is disposed to overlap the first pixel area.
